(19) United States
(12) Patent Application Publication
(10) Pub. No.: US 2006/0078023 A1
(43) Pub. Date: Apr. 13, 2006

(54) Laser diode and method of fabricating the same

(75) Inventor: Dae-ho Lim, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: SAMSUNG ELECTRO-MECHANICS CO., LTD., Gyeonggi-do (KR)

(21) Appl. No.: 11/128,313

(22) Filed: May 13, 2005

(30) Foreign Application Priority Data
Oct. 9, 2004 (KR) 10-2004-0080726

(51) Int. Cl. H01S 5/20

(52) U.S. Cl. 372/45.01

(57) ABSTRACT

A laser diode and a method of fabricating the same are provided. An embodiment of the laser includes a substrate; at least one material layer formed on the substrate and having a current passing region and a current block region which is composed of oxide and disposed at both sides of the current passing region; and a laser oscillating layer formed on the material layer.

### CROSS-REFERENCE TO RELATED PATENT APPLICATIONS

This application claims the benefit of Korean Patent Application No. 10-2004-0080726, filed on Oct. 9, 2004, in the Korean Intellectual Property Office, the disclosure of which is incorporated herein in its entirety by reference.

### BACKGROUND

1. Field of the Invention

The present invention relates to a laser diode and a method of fabricating the same, and more particularly, to a laser diode, the size of its current passing region being easily controllable, and a method of fabricating the same further simplified in manufacture processing.

2. Description of the Related Art

Generally, since a semiconductor laser diode is relatively small-sized, and a threshold current for oscillating semiconductor laser is lower than that of a typical laser device, it is widely used in communication systems for high speed data transmission, players using optical disks for recording and reading data at high speed, and the like.

FIG. 1 is a sectional view illustrating a typical laser diode. Referring to FIG. 1, the laser diode is structured such that an n-GaAs lower buffer layer 2, a p⁻-GaInP current block layer 3, an n-AlInGaP lower clad layer 4, an InGaP active layer 5, a p-AlInGaP upper clad layer 6, a p-InGaAs upper buffer layer 7, a p⁺-GaAs cap layer 8 are sequentially formed on an n-GaAs substrate 1. The current block layer 3 is formed on the lower buffer layer 2, and is shaped with separation by a predetermined distance. Further, an n-electrode 14 is formed on the bottom surface of the substrate 1, and a p-electrode 13 is formed on the upper surface of the cap layer 8. The superscript “p⁻-” of the current block layer 3 means a doping level slightly lower than the p-type doping level referred to as “p-” to form a typical p-type semiconductor, and the superscript “p⁺-” of the cap layer 8 means a doping level slightly higher than the p-type doping level referred to as “p-” to form a typical p-type semiconductor. The reference number “11” refers to a laser beam emitting region for emitting laser beam, and the reference number “12” refers to a current passing region for passing a restricted current.

The laser diode structured as above has advantages of easily controlling a transverse mode by a V-channel formed by the current block layer 3 and the current passing region 12, and reducing a threshold current for starting laser oscillation. However, the fabrication of such a laser diode has drawbacks requiring two steps of growing processing and performing a lithography process before a second growth. Further, as the V-channel has a very narrow region, a good quality of an active layer is difficult to grow and even the grown active layer is unstable.

### SUMMARY

An embodiment of the present invention provides a laser diode and a method of fabricating the same being capable of easily controlling the size of a current passing region and simplifying the fabrication processing.

According to an aspect of the present invention, there may be provided a laser diode including a substrate; at least one material layer formed on the substrate, and having a current passing region and a current block region composed of oxide and disposed at both sides of the current passing region; and a laser oscillating layer formed on the material layer.

The substrate may be composed of n-GaAs. In this case, preferably, the current passing region may be composed of n-AlₓGa₁₋ₓAs (0.5≦x≦1), and the current block region may be composed of n-AlₓGa₁₋ₓAs oxide.

An n-GaAs layer may be formed between the material layers.

Preferably, the width of the current passing region may be in the range of about 0.5 to about 100 μm, and each of the material layers has a thickness of about 20 to about 1000 nm.

The material layers disposed closer to the substrate may have greater thicknesses, or the material layers disposed closer to the substrate may have smaller thicknesses. Alternatively, the material layers may have same thicknesses.

The current block regions disposed closer to the substrate may have greater contents of Al, and the current block regions disposed closer to the substrate may have smaller contents of Al. Alternatively, the current block regions may have same contents of Al.

The laser oscillating layer may include an active layer, and upper and lower clad layers disposed on and below the active layer respectively. Here, preferably, the active layer is composed of InGaP, and the upper and lower clad layers are composed of p-InGaAlP and n-InGaAlP respectively.

A buffer layer composed of n-GaAs may be formed between the substrate and the material layer, and a cap layer composed of p-GaAs may be formed on the laser oscillating layer. A highly conductive layer composed of p-InGaP may be formed between the laser oscillating layer and the cap layer.

An n-electrode and a p-electrode may be formed below the substrate and on the cap layer, respectively.

According to another aspect of the present invention, there may be provided a method of fabricating a laser diode including forming an n-GaAs buffer layer on an n-GaAs substrate; forming at least one n-AlₓGa₁₋ₓAs layer (0.5≦x≦1) on the n-GaAs buffer layer; sequentially forming an n-InGaAlP lower clad layer, an InGaP active layer, a p-InGaAlP upper clad layer, a p-InGaP highly conductive layer, and a p-GaAs cap layer; oxidizing both sides of the n-AlₓGa₁₋ₓAs layer, thereby forming a current block region; and forming an n-electrode and a p-electrode below the n-GaAs substrate and on the p-GaAs cap layer, respectively.

Preferably, the both sides of the n-AlₓGa₁₋ₓAs layer is oxidized by a selective wet oxidation method.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view illustrating a conventional laser diode;

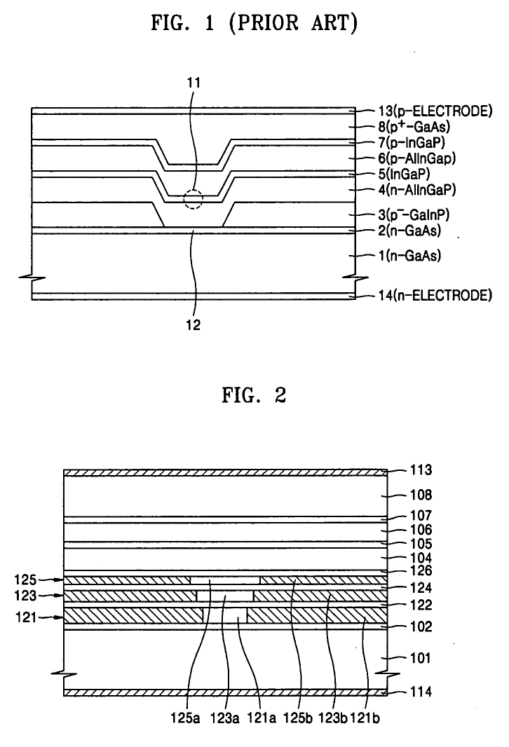

FIG. 2 is a sectional view illustrating a laser diode according to an embodiment of the present invention; and

FIGS. 3A through 3C are sectional views illustrating a method of fabricating a laser diode according to an embodiment of the present invention.

### DETAILED DESCRIPTION OF EXEMPLARY EMBODIMENTS OF THE INVENTION

Embodiments of the present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like numbers refer to like elements throughout the specification.

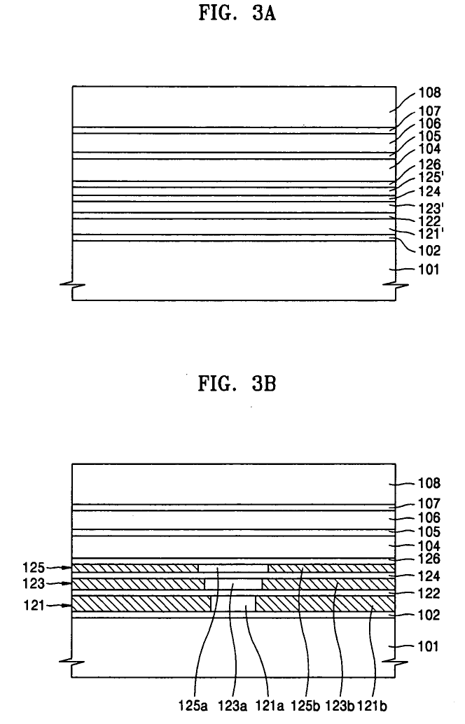

FIG. 2 is a sectional view illustrating a laser diode according to an embodiment of the present invention. Referring to FIG. 2, the laser diode according to an embodiment of the present invention may include a substrate 101, at least one material layer 121, 123, 125 formed on the substrate 101, and a laser oscillation layer formed on the material layers 121, 123, 125.

The substrate 101 may be an n-GaAs substrate. A buffer layer 102, which is composed of an n-GaAs layer, may be further formed on the substrate 101.

At least one material layer 121, 123, 125 is formed on the buffer layer 102. Each of the material layers 121, 123, 125 may have a thickness of about 20 to about 1000 nm. In FIG. 2, three material layers 121, 123, 125 are depicted, which is not restrictive. Therefore, a plurality of various material layers may be formed in the present invention. N-GaAs layers 122, 124 may be formed between the material layers 121, 123, 125, and an n-GaAs layer 126 may be further formed on the uppermost material layer 125.

The material layers 121, 123, 125, respectively, may include current passing regions 121a, 123a, 125a and current block regions 121b, 123b, 125b disposed at both sides of the current passing regions 121a, 123a, 125a. Each of the current passing regions 121a, 123a, 125a may be formed to have a width of about 1.5 to about 100 μm.

The current passing regions 121a, 123a, 125a may be composed of n-AlₓGa₁₋ₓAs (0.5≦x≦1), and the current block regions 121b, 123b, 125b may be composed of n-AlₓGa₁₋ₓAs oxide formed by wet-oxidizing the n-AlₓGa₁₋ₓAs.

The width of each of the current passing regions 121a, 123a, 125a may be controlled by varying the thicknesses of the material layers 121, 123, 125. In specific, if the material layers 121, 123, 125 are formed in thicker toward the substrate 101, the oxidation speed of the n-AlₓGa₁₋ₓAs may be increased so that the widths of the current passing regions 121a, 123a, 125a are further reduced toward the substrate 101 as shown in FIG. 2. In the embodiments, the material layers 121, 123, 125 may be formed in thinner toward the substrate 101 such that the widths of the current passing regions 121a, 123a, 125a are further increased toward the substrate 101. Alternatively, the material layers 121, 123, 125 may be formed with a same thickness such that the widths of the current passing regions 121a, 123a, 125a are all same.

Further, the width of each of the current passing regions 121a, 123a, 125a may be controlled by varying the content of Al in the n-AlₓGa₁₋ₓAs. In specific, if the material layers 121, 123, 125 are formed with higher content of Al toward the substrate 101, the oxidation speed of the n-AlₓGa₁₋ₓAs may be increased so that the widths of the current passing regions 121a, 123a, 125a are further reduced toward the substrate 101. In the embodiments, the material layers 121, 123, 125 may be formed with lower content of Al toward the substrate 101 such that the widths of the current passing regions 121a, 123a, 125a are further increased toward the substrate 101. Alternatively, the material layers 121, 123, 125 may be formed with a same content of Al such that the widths of the current passing regions 121a, 123a, 125a are all same.

A laser oscillation layer formed on the material layers 121, 123, 125 may include an active layer 105, and an upper clad layer 106 and a lower clad layer 104 disposed on and below the active layer 105, respectively. The active layer 105 may be composed of InGaP. The upper clad layer 106 and the lower clad layer 104 may be composed of p-InGaAlP and n-InGaAlP respectively.

A highly conductive layer 107, which may be composed of p-InGaP, is formed on the upper clad layer 106, and a cap layer 108, which may be composed of p-GaAs, is formed on the highly conductive layer 107. An n-electrode 114 may be formed below the substrate 101 and a p-electrode 113 is formed on the cap layer 108.

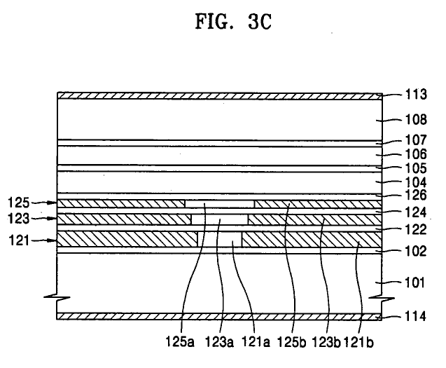

Hereinafter, a method of fabricating a laser diode according an embodiment of the present invention will be described in reference to FIGS. 3A through 3C.

Referring to FIG. 3A, an n-GaAs buffer layer 102 may be formed on an n-GaAs substrate 101. At least one of n-AlₓGa₁₋ₓAs layers (0.5≦x≦1) 121′, 123′, 125′ may be formed on the buffer layer 102. The n-AlₓGa₁₋ₓAs layers 121′, 123′, 125′ may be respectively formed with different thicknesses or with different contents of Al to control the widths of current passing regions. N-GaAs layers 122, 124 may be formed between the n-AlₓGa₁₋ₓAs layers 121′, 123′, 125′, and an n-GaAs layer 126 may be formed on the uppermost n-AlₓGa₁₋ₓAs layer 125′. Then, an n-InGaAlP lower clad layer 104, an InGaP active layer 105, a p-InGaAlP upper clad layer 106, a p-InGaP highly conductive layer 107, and a p-GaAs cap layer 108 may be sequentially formed on the n-GaAs layer 126.

Then, referring to FIG. 3B, the n-AlₓGa₁₋ₓAs layers 121′, 123′, 12′ may be oxidized by a selective wet oxidation method from the both sides of the resultant layers shown in FIG. 3A, so that material layers 121, 123, 125 may be formed, in which the material layers 121, 123, 125, respectively, may include current passing regions 121a, 123a, 125a and current block regions 121b, 123b, 125b disposed at both sides of the current passing regions 121a, 123a, 125a. The current passing regions 121a, 123a, 125a may be composed of n-AlₓGa₁₋ₓAs, and the current block regions 121b, 123b, 125b may be composed of n-AlₓGa₁₋ₓAs oxide.

Lastly, referring to FIG. 3C, an n-electrode 114 may be formed below the substrate 101 and a p-electrode 113 may be formed on the cap layer 108, so that the fabrication of a laser diode according to an embodiment of the present invention may be completed.

As described above, since the current block regions of the laser diode according to the present invention are composed of oxide, the widths of the current passing regions may be freely controlled. Accordingly, multi-transverse mode suppressing and index guiding effects can be achieved. Further, in the method of fabricating the laser diode according to the present invention, the laser diode may be fabricated in a monolithic structure by one growing step.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A laser diode comprising:
a substrate;
at least one material layer formed on the substrate, and including a current passing region and a current block region composed of oxide and disposed at both sides of the current passing region; and
a laser oscillating layer formed on the material layer.

2. The laser diode of claim 1, wherein the substrate is composed of n-GaAs.

3. The laser diode of claim 2, wherein the current passing region is composed of n-AlₓGa₁₋ₓAs (0.5≦x≦1), and the current block region is composed of n-AlₓGa₁₋ₓAs oxide.

4. The laser diode of claim 3, wherein an n-GaAs layer is formed between the material layers.

5. The laser diode of claim 3, wherein the width of the current passing region is in the range of about 0.5 to about 100 μm.

6. The laser diode of claim 3, wherein each of the material layers has a thickness of about 20 to about 1000 nm.

7. The laser diode of claim 3, wherein the material layers disposed closer to the substrate have greater thicknesses.

8. The laser diode of claim 3, wherein the material layers disposed closer to the substrate have smaller thicknesses.

9. The laser diode of claim 3, wherein the material layers have same thicknesses.

10. The laser diode of claim 3, wherein the current block regions disposed closer to the substrate have greater contents of Al.

11. The laser diode of claim 3, wherein the current block regions disposed closer to the substrate have smaller contents of Al.

12. The laser diode of claim 3, wherein the current block regions have same contents of Al.

13. The laser diode of claim 3, wherein the laser oscillating layer includes an active layer, and upper and lower clad layers disposed on and below the active layer respectively.

14. The laser diode of claim 13, wherein the active layer is composed of InGaP, and the upper and lower clad layers are composed of p-InGaAlP and n-InGaAlP respectively.

15. The laser diode of claim 14, wherein a buffer layer composed of n-GaAs is formed between the substrate and the material layer.

16. The laser diode of claim 15, wherein a cap layer composed of p-GaAs is formed on the laser oscillating layer.

17. The laser diode of claim 16, wherein a highly conductive layer composed of p-InGaP is formed between the laser oscillating layer and the cap layer.

18. The laser diode of claim 17, wherein an n-electrode and a p-electrode are formed below the substrate and on the cap layer respectively.

19. A method of fabricating a laser diode comprising:
forming an n-GaAs buffer layer on an n-GaAs substrate;
forming at least one n-AlₓGa₁₋ₓAs layer (0.5≦x≦1) on the n-GaAs buffer layer;
sequentially forming an n-InGaAlP lower clad layer, an InGaP active layer, a p-InGaAlP upper clad layer, a p-InGaP highly conductive layer, and a p-GaAs cap layer;
oxidizing both sides of the n-AlₓGa₁₋ₓAs layer, thereby forming a current block region; and
forming an n-electrode and a p-electrode below the n-GaAs substrate and on the p-GaAs cap layer respectively.

20. The method of claim 19, wherein the both sides of the n-AlₓGa₁₋ₓAs layer is oxidized by a selective wet oxidation method.

21. The method of claim 19, wherein an n-GaAs layer is formed between the n-AlₓGa₁₋ₓAs layers.
